(19) United States
(12) Patent Application Publication
(10) Pub. No.: US 2003/0104139 A1
(43) Pub. Date: Jun. 5, 2003

(54) Apparatus for depositing a plasma chemical vapor deposition coating on the inside of an optical fiber preform

(76) Inventors: Keith L. House, Corning, NY (US); Samir Khanna, Painted Post, NY (US); Barton G. Lane III, Belmont, MA (US); Prantik Mazumder, Corning, NY (US)

Correspondence Address: CORNING INCORPORATED, SP-TI-3-1, CORNING, NY, 14831

(21) Appl. No.: 10/104,873

(22) Filed: Mar. 22, 2002

Related U.S. Application Data
(60) Provisional application No. 60/334,976, filed on Nov. 30, 2001.

(51) Int. Cl. C23C 16/00

(52) U.S. Cl. 427/569; 118/723 MW; 427/255.28

(57) ABSTRACT

This present invention is directed to an apparatus for depositing a plasma chemical vapor deposition (PCVD) coating on the inside of a preform used for the drawing of optical fibers. This invention further relates to a novel microwave applicator design used in the apparatus; preferably allowing for a more intense, circumferentially symmetric plasma about the longitudinal axis of the preform, under normal operating conditions; resulting in a more uniform coating and a reduced applicator length, and a method for making the coated preform.

### CROSS-REFERENCE TO RELATED APPLICATIONS

This application claims the benefit of priority under 35 U.S.C. § 119(e) of U.S. Provisional Application No. 60/334,976 filed on Nov. 30, 2001.

### BACKGROUND OF THE INVENTION

1. Field of the Invention

This invention relates to an apparatus for depositing a plasma chemical vapor deposition (PCVD) coating on the inside of a preform used for the drawing of optical fibers. This invention further relates to a novel microwave applicator design used in the apparatus; preferably allowing for a more intense, circumferentially symmetric plasma about the longitudinal axis of the preform, under normal operating conditions; resulting in a more uniform coating and a reduced applicator length, and a method for making the coated preform.

2. Technology Background

Optical fibers have acquired an increasingly important role in the field of communications, frequently replacing existing copper wires. Interference with the light beam or its partial loss during transmission must be at a minimum to make the use of optical fibers a successful communications technology. The manufacture of optical fibers is a complicated, expensive, technical process involving many steps. Improvements to many of these steps ultimately result in improvements in the overall quality and cost of making the optical fiber.

Optical fibers can be formed by drawing a fiber either from a hollow or collapsed optical fiber preform. The term optical fiber preform, as used herein, included preforms which are coated by a process in which a glass coating(s) is deposited on an internal and/or external surface of a glass tube. The number of glass coating layers, the composition of the coating and the surface(s) of the glass tube on which the coating is deposited are determined based on the type of fiber to be manufactured (e.g., step-index multimode, graded-index multimode, step-index single-mode, dispersion-shifted single-mode, and dispersion-flattened single-mode). An important step in the manufacture of an optical fiber is the formation of the preform. The glass coatings, which make up the preform can be deposited by a number of deposition techniques. One of these techniques is the PCVD process.

In the PCVD process for coating a preform, thin layers of fully consolidated glass are deposited along the inner surface of a silica tube by a plasma-enabled oxidation of SiCl₄. The plasma in this process is generated inside the tube by the application of microwaves to the feed gases within the tube (e.g., SiCl₄, GeCl₄, and O₂) at low pressures (typically approximately 10 Torr). The tube passes through the microwave applicator 10, also called an activator chamber or activator head as shown in FIG. 1. Microwaves are fed to the applicator through a waveguide 12 thereby forming an electro-magnetic field around and inside the glass tube. This field is used to initiate and sustain a plasma in the tube that enables the chemical reactions that deposit the glass on the inside of the tube.

The microwave applicator plays an important role in the quality of the deposited glass coating, as well as in the overall performance of the PCVD process. The primary affect of the applicator is on the shape of the plasma inside the tube, which affects the overall quality of the deposited glass coating. In the applicator design shown in FIG. 1, the microwave field has a uniform intensity along the longitudinal axis of the glass tube, and a sinusoidal intensity along the diameter of the glass tube perpendicular to the elongated axis of the waveguide. The uniform axial intensity will tend to generate a more diffuse plasma, spreading the plasma over a longer axial distance. This results in the need for a longer applicator head design, and therefore in a shorter usable length of preform. The sinusoidal variation along the tube diameter tends to accentuate the circumferential asymmetry of the plasma, especially for larger diameter tubes. This potentially (depending on other deposition conditions) results in a circumferentially non-uniform coating. Therefore in order to make uniform coatings using current applicator designs, the deposition rate must be reduced and the applicator head design must be longer to improve the uniformity of the coating, thereby resulting in a slower, less efficient process.

### SUMMARY OF THE INVENTION

One aspect of the present invention is directed to an apparatus for depositing a plasma chemical vapor deposition (PCVD) coating on the inside of a tube; thereby, forming an optical fiber preform which can be used for the drawing of optical fibers.

In one embodiment, the present invention includes an apparatus for depositing a plasma chemical vapor deposition glass coating on the inside of a glass tube comprising a) a waveguide for carrying microwaves with an elongated axis, the waveguide having a rectangular cross-section perpendicular to the elongated axis, the rectangular cross-section having a long and a short axis; and b) an applicator head for application of microwaves having a chamber and two circular openings on both ends of the chamber configured to allow the applicator head to move over a glass tube or for moving a glass tube through, along its longitudinal axis; wherein the waveguide emerges into the applicator head with the long axis of the rectangular cross-section of the waveguide substantially parallel to the longitudinal axis of the glass tube.

In another embodiment, the present invention includes a method of depositing a plasma chemical vapor deposition glass coating on the inside of a glass tube comprising the steps of flowing a mixture of gases through a glass tube having an inside surface; heating the glass tube and the mixture of gases flowing through the tube to a temperature greater than about 1000° C.; applying microwaves to the glass tube wherein the microwaves are applied with an apparatus comprising a waveguide for carrying microwaves with an elongated axis, the waveguide having a rectangular cross-section perpendicular to the elongated axis, the rectangular cross-section having a long and a short axis; and an applicator head for application of microwaves said applicator head having a chamber and two circular openings on both ends of the chamber, said openings configured to allow the applicator head to move over the glass tube or for moving the glass tube there through along a longitudinal axis of the glass tube wherein the waveguide emerges into the applicator head with the long axis of the rectangular cross-section of the waveguide substantially parallel to the longitudinal axis of the glass tube; and forming a glass coating on the inside of the glass tube.

In another embodiment, the present invention includes an apparatus for depositing a plasma chemical vapor deposition glass coating on the inside of a glass tube comprising a) a waveguide for carrying microwaves with an elongated axis, the waveguide having a rectangular cross-section perpendicular to the elongated axis, the rectangular cross-section having a long and a short axis; and b) an applicator head for application of microwaves to a glass tube, the applicator head being substantially cylindrical comprising an outer wall with an inside surface and two parallel end walls each with a centered, circular opening for moving the applicator head over a glass tube or for moving a glass tube through, the waveguide emerging into the applicator head tangent to the inside surface of the outer wall of the applicator head.

An advantage of the above embodiments is to provide novel microwave applicator designs used in the apparatus which preferably allow for a more intense, circumferentially symmetric plasma, under normal operating conditions; thereby, resulting in a more uniform coating.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description are merely exemplary of the invention, and are intended to provide an overview or framework for understanding the nature and character of the invention as it is claimed. The accompanying drawings are included to provide a further understanding of the invention, and are incorporated in and constitute a part of this specification. The drawings illustrate various embodiments of the invention, and together with the description serve to explain the principles and operation of the invention.

### BRIEF DESCRIPTION OF THE DRAWINGS

FIG. 1 is a schematic of prior art microwave applicator design.

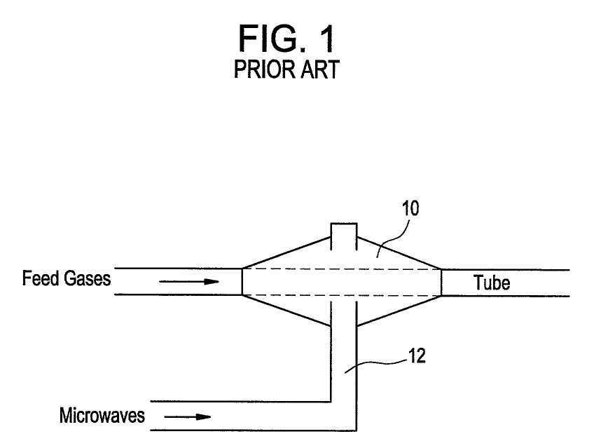

FIGS. 2 a, b, and c are cross-sectional views of a microwave applicator design viewed from three different axes.

FIG. 3 is a perspective view of the microwave applicator in FIG. 2 with a twisted waveguide.

FIGS. 4 a, b and c are cross-sectional views of another microwave applicator design viewed from three different axes.

### DETAILED DESCRIPTION OF THE INVENTION'S PREFERRED EMBODIMENTS

The present invention is directed to an apparatus and a microwave applicator used in the apparatus for producing coated glass tubes used for the production of optical fibers. The apparatus and the applicator preferably produce a tube, which is more uniformly coated across the deposition zone.

Reference will now be made in detail to the present preferred embodiments of the invention, examples of which are illustrated in the accompanying drawings. Wherever possible, the same reference numbers will be used throughout the drawings to refer to the same or like parts.

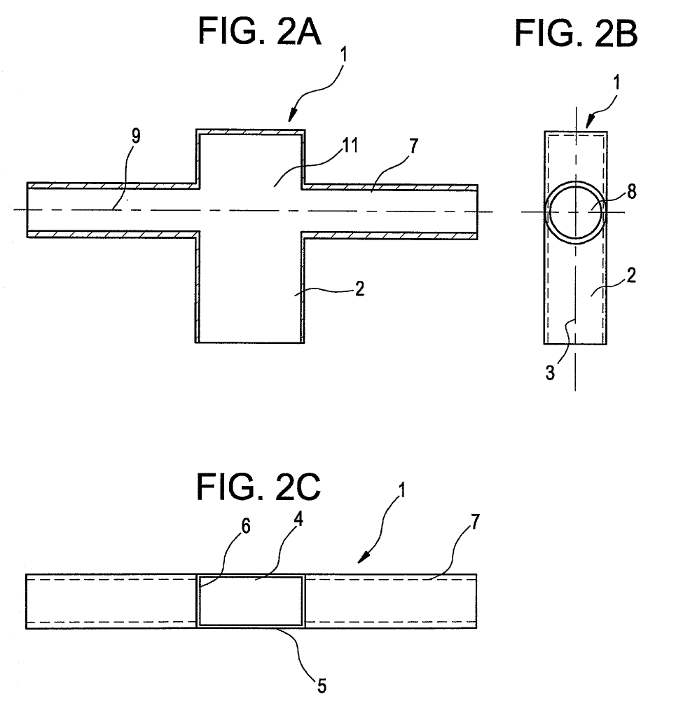

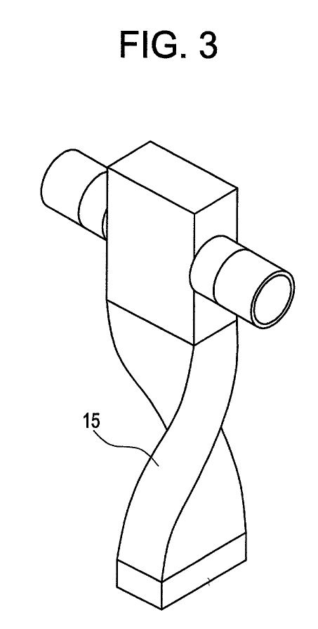

One embodiment of the present invention is directed to an apparatus for depositing a PCVD coating on the inside of a glass tube. This apparatus shown in FIGS. 2 a, b and c, and 3 in its simplest form comprises an applicator 1. The applicator 1 comprises a waveguide 2 and an applicator head 7. The waveguide 2 is used to guide microwaves from a microwave generator (not shown) to the applicator head 7. The waveguide 2 has an elongated axis 3 and a rectangular cross-section 4. The rectangular cross section 4 has a long axis 5 and a short axis 6, and is perpendicular to the elongated axis 3 of the waveguide 2. Preferably, at least a portion 15 of the waveguide is twisted 90° as is shown in FIG. 3.

The applicator head 7 is used to apply microwaves to a glass tube (not shown), which is positioned within the applicator head 7. The glass tube is provided with a mixture of gases flowing through it, which dissociate when exposed to the microwaves to create a plasma in the glass tube. The applicator head 7 includes a chamber 11, the walls of the applicator head 7 defining the chamber 11, which is interposed between two circular openings 8 on both ends of the chamber 11 to allow the applicator head 7 to move over a glass tube in which a coating is deposited, or for moving a glass tube through along its longitudinal axis. The applicator 1 can be used to produce a uniform coating on large diameter glass tubes, therefore in order to accommodate larger diameter tubes preferably, the two openings 8 have diameters greater than about 30 mm, more preferably greater than about 40 mm and most preferably greater than about 50 mm. The waveguide 2 emerges into the chamber 11 of the applicator head 7, and preferably is integral with the applicator head 7. Preferably, the length of the applicator head 7 along it's long axis 5 between the two circular openings 8 is preferably less than about 19 cm, more preferably less than about 17.5 cm, even more preferably less than about 15 cm and most preferably less than about 12.5 cm. It was found that the shorter the length of the applicator head 7, the longer the usable length of the preform. The long axis 5 of the rectangular cross section of the waveguide 2 is substantially parallel, and more preferably parallel, to the longitudinal axis of the glass tube. By substantially parallel, it is meant it is preferably within 15° of parallel, more preferably within 10° of parallel and most preferably within 5° of parallel. Preferably, the waveguide 2 emerges into the center of the chamber 11 of the applicator head 7. Even more preferably, the chamber 11 (except in the area where the waveguide 2 emerges into the chamber 11) is substantially circumferentially symmetric about the longitudinal axis 9 between the two openings 8. Also further preferably, the chamber has no inner wall or other obstruction blocking or diverting the path of the microwaves between where the waveguide 2 emerges in the applicator head 7 and the glass tube.

Preferably, the incoming microwave field in the applicator head 7 is substantially uniform across the diameter of the tube perpendicular to the elongated axis of the waveguide. By substantially uniform, it is meant that minimum and maximum intensity in the microwave field across the diameter varies in intensity from the average intensity of the field across the diameter by preferably less than 10%, and more preferably by less than 5%, and most preferably by less than 2% as measured with no plasma and gases in the glass tube. Preferably, the incoming microwave field in the applicator head 7 prior to entering the glass tube is substantially sinusoidal along the longitudinal axis of the glass tube. By substantially sinusoidal, it is meant that the amplitude of intensity at each point along the longitudinal axis of the glass tube is substantially proportional to the sine of the phase angle of intensity, and preferably the intensity of the microwave field at any given point between the maximum and minimum intensities along the longitudinal axis of the glass tube is within 20% of an intensity which would approximate a sine wave, and more preferably within 10%. Further preferably, the intensity of the microwave field along the longitudinal axis of the glass tube has a minimum which is less than 50% of the intensity of the maximum, more preferably a minimum which is less than 20% of the intensity of the maximum, even more preferably a minimum which is less than 10% of the intensity of the maximum, and most preferably a minimum which is less than 5% of the intensity of the maximum. The uniformity of the microwave field across the diameter of the tube preferably improves the circumferential symmetry of the plasma and ultimately the coating, especially in large diameter tubes. The sinusoidal variation along the longitudinal axis of the glass tube generating the most intense plasma preferably in the glass tube at a point at or near the intersection of the longitudinal axes of the tube and the waveguide which is preferably near the center of the waveguide 2 where it emerges 10 into the chamber 11 which is more preferably at the center of the applicator chamber 11 (the intensity of the plasma decreasing gradually in a sinusoidal fashion on either side of the point). The gradually tapering plasma on either side of the applicator's 7 center helps keep the neutral gas temperatures above the vaporization temperatures of SiO₂ thereby preventing substantial soot formation, and preferably preventing any soot formation.

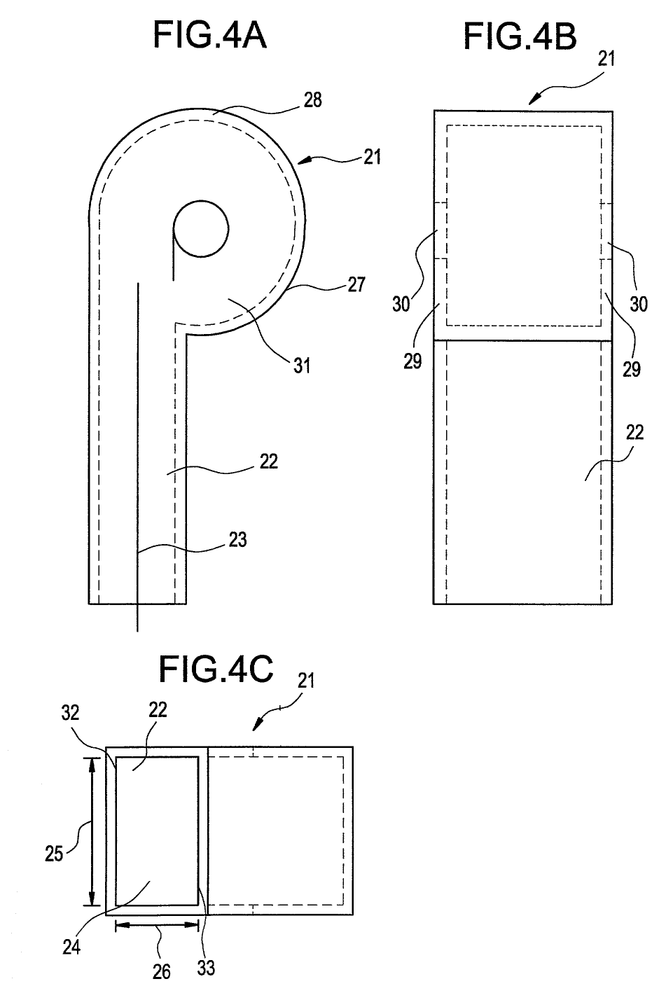

Another embodiment of the present invention is also directed to an apparatus for depositing a PCVD coating on the inside of a glass tube. This apparatus shown in FIGS. 4 a, b and c in its simplest form comprises an applicator 21. The applicator 21 comprises a waveguide 22 and an applicator head 27. The waveguide 22 is used to carry microwaves from a microwave generator (not shown) to the applicator head 27. The waveguide 22 having four walls, an elongated axis 23 and a rectangular cross-section 24. The rectangular cross section 24 has a long axis 25 and a short axis 26, and is perpendicular to the elongated axis 23 of the waveguide 22.

The applicator head 27 is used to apply microwaves to a glass tube with a mixture of gases flowing through it, to create a plasma in the glass tube. The applicator head 27 and the applicator chamber 31 are substantially cylindrical. By substantially cylindrical, it is meant that the applicator head 27 and applicator chamber 31 are cylindrical except where the waveguide 22 emerges into the chamber 31. The applicator head 27 having an outer wall 28 having an inside surface and two parallel end walls 29 which essentially define the applicator chamber 31. The two parallel end walls 29 each have a centered, circular opening 30, which allows the applicator head 27 to move over a glass tube in which a coating is deposited, or for moving a glass tube through, along the glass tubes longitudinal axis. Waveguide 22 emerges into applicator chamber 31 with a first wall 32 of the waveguide 22 at least substantially tangent to the inside surface of the outer wall 28 of the applicator head 27, and preferably being integral with the applicator head 27. More preferably, the second wall 33 of the waveguide which is parallel to the first wall 32 can enter the chamber 31 on a plane which is at least substantially tangent to the circular openings 30 wherein the distance between the first 32 and second walls 33 is less than the inner radius of the cylindrical chamber 27.

Preferably, the apparatus of the above embodiments may also include a glass tube, a gas supply device for supplying a mixture of gases to the glass tube, and an oven (not shown) for heating the tube and the gases. Preferably, the glass tube is transparent to the energy being applied via the applicator (e.g., microwave, radio frequency, etc) if the coating is to be formed on the inside of the substrate tube. Also preferably, the substrate tube is made from glass, and more preferably is from high purity fused silica.

The oven for heating the substrate tube and the gases can be any type known to those skilled in the art. Preferably, the oven can heat the substrate tube and the gases to above about 1000° C., more preferably above about 1100° C. and most preferably above about 1200° C. To prevent loss of energy and to reduce temperature fluctuations in the oven, preferably the oven is well insulated with a refractory (or insulating) material. Preferably, the applicator head 7 and at least a portion of the waveguide 2 are mounted within the oven.

The gas supply device for supplying a mixture of gases into the substrate tube can be any type known to those skilled in the art. The gas supply device consists of the proper piping, valves, monitors to allow for the proper mixing and delivery of the desired admixture of gases and vapors to the glass tube to form the desired coating (layer(s) of glass) on the glass tube. Preferably, the basic gases supplied are SiCl₄ and O₂, however, depending on the properties desired for the core of the optical fiber ultimately produced various modifiers and/or dopants such as GeCl₄ or C₂F₆ can be added through the addition of other gases.

Another embodiment of the present invention is directed to a method of depositing a PCVD coating on the inside of a glass tube. This method comprises the steps of flowing a mixture of gases through a glass tube, heating the glass tube along with the gases flowing through the tube, applying microwaves to the tube, and forming a glass coating on the inside of the tube. Preferably, the glass tube and gases flowing through the tube are heated to temperatures greater than about 1000° C., more preferably greater than about 1100° C. and most preferably greater than about 1200° C. Preferably, the mixture of gases flowing through the glass tube comprises SiCl₄ and O₂.

The microwave field applied to the glass tube in this embodiment is substantially uniform across the diameter of the tube, which is perpendicular to the elongated axis of the waveguide 2 of the applicator 1 and is substantially sinusoidal along the longitudinal axis of the tube. More preferably, microwaves are applied using an apparatus comprising a waveguide for carrying microwaves with an elongated axis, the waveguide having a rectangular cross-section perpendicular to the elongated axis, the rectangular cross-section having a long and a short axis; and an applicator with a chamber and two circular openings on either end of the chamber configured to allow the applicator to move over a glass tube or for moving a glass tube through along its longitudinal axis; wherein the waveguide emerges into the applicator with the long axis of the rectangular cross-section of the wave guide substantially parallel to where the longitudinal axis of the glass tube would be when the applicator is in use.

All of the above embodiments can be used to help process both single-mode and multi-mode preforms for optical fibers manufactured by processes in which a glass or quartz tube is coated with at least one vitreous, crystalline or semi-crystalline oxide coating using a PCVD coating process. More preferably, the present invention is used to prepare coatings, which are applied to the inside of the glass or high purity fused silica preform tube. Preferably, the preforms prior to coating have an inner diameter of from about 19 to about 29 mm, an outer diameter of from about 25 to about 35 mm, and a wall thickness of from about 2 to about 6 mm. The coating comprises at least one layer of glass, but could comprise up to several hundred layers of glass (e.g., preforms for graded index multimode fibers are made by depositing up to several hundred layers of vitreous oxide coatings to approximate a smooth curve). The thickness of the coating and the number of layers (and their thickness and composition) to the coating depends on the type of optical fiber for which the preform is being used (e.g., step-index multimode, graded-index multimode, step-index single-mode, dispersion shifted single-mode, or dispersion flattened single-mode fibers). Preferably, however, the coating thickness is from about 1000 to about 4000 μm.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

What is claimed:

1. An apparatus for depositing a plasma chemical vapor deposition glass coating on the inside of a glass tube comprising:
a) a waveguide for carrying microwaves with an elongated axis, the waveguide having a rectangular cross-section perpendicular to the elongated axis, the rectangular cross-section having a long and a short axis; and
b) an applicator head for application of microwaves said applicator head having a chamber and two circular openings on both ends of the chamber, said openings configured to allow the applicator to move over a glass tube or for moving the glass tube there through along a longitudinal axis of the glass tube;
wherein the waveguide emerges into the applicator with the long axis of the rectangular cross-section of the waveguide substantially parallel to the longitudinal axis of the glass tube.

2. The apparatus in claim 1, wherein the rectangular cross-section of the waveguide is twisted 90°.

3. The apparatus in claim 1, wherein the apparatus is capable of applying a microwave field to a glass tube with a longitudinal axis and a diameter that is substantially uniform across the diameter of the tube perpendicular to the elongated axis of the waveguide and is substantially sinusoidal along the longitudinal axis of the tube.

4. The apparatus in claim 2, wherein the apparatus is capable of applying a microwave field to a glass tube with a longitudinal axis and a diameter that is substantially uniform across the diameter of the tube perpendicular to the elongated axis of the waveguide and is substantially sinusoidal along the longitudinal axis of the tube.

5. The apparatus in claim 3, wherein the length of the applicator head between the two circular openings is less than about 19 cm.

6. The apparatus in claim 1, further comprising an oven capable of heating the glass tube to temperatures above about 1000° C. in which the applicator head and at least a portion of the waveguide are mounted.

7. The apparatus in claim 3, wherein the length of the applicator head between the two circular openings is less than about 15 cm.

8. The apparatus in claim 3, wherein the length of the applicator head between the two circular openings is less than about 12.5 cm.

9. The apparatus in claim 5, further comprising an oven capable of heating the glass tube to temperatures above about 1000° C. in which the applicator head and at least a portion of the waveguide are mounted.

10. The apparatus in claim 7, further comprising an oven capable of heating the glass tube to temperatures above about 1000° C. in which the applicator head and at least a portion of the waveguide are mounted.

11. The apparatus in claim 8, further comprising an oven capable of heating the glass tube to temperatures above about 1000° C. in which the applicator head and at least a portion of the waveguide are mounted.

12. The apparatus in claim 9, where in the circular openings have a diameter greater than about 40 mm.

13. The apparatus in claim 10, wherein the circular openings have a diameter greater than about 40 mm.

14. The apparatus in claim 11, wherein the circular openings have a diameter greater than about 40 mm.

15. A method of depositing a plasma chemical vapor deposition glass coating on the inside of a glass tube comprising the steps of:
a) flowing a mixture of gases through a glass tube having an inside surface;
b) heating the glass tube and the mixture of gases flowing through the tube to a temperature greater than about 1000° C.; and
c) applying microwaves to the glass tube;
wherein the microwaves are applied with an apparatus comprising:
i) a waveguide for carrying microwaves with an elongated axis, the waveguide having a rectangular cross-section perpendicular to the elongated axis, the rectangular cross-section having a long and a short axis; and
ii) an applicator head for application of microwaves said applicator head having a chamber and two circular openings on both ends of the chamber, said openings configured to allow the applicator to move over the glass tube or for moving the glass tube there through along a longitudinal axis of the glass tube;
wherein the waveguide emerges into the applicator head with the long axis of the rectangular cross-section of the waveguide substantially parallel to the longitudinal axis of the glass tube; and
d) forming a glass coating on the inside surface of the glass tube.

16. The method in claim 15, wherein the mixture of gases comprises SiCl₄ and O₂.

17. The method in claim 16, wherein the tube has a diameter and the microwaves are applied substantially uniformly across the diameter of the tube perpendicular to the elongated axis of the waveguide and substantially sinusoidally along the longitudinal axis of the tube.

18. The method in claim 17, wherein the length of the applicator head between the two circular openings is less than about 19 cm.

19. The method in claim 18, wherein the circular openings have a diameter greater than about 40 mm.

20. An apparatus for depositing a plasma chemical vapor deposition coating on the inside of a glass tube comprising:
a) a waveguide for carrying microwaves with an elongated axis, the waveguide having a rectangular cross-section perpendicular to the elongated axis, the rectangular cross-section having a long and a short axis; and
b) an applicator head for application of microwaves to a glass tube, the applicator head being substantially cylindrical comprising an outer wall with an inside surface and two parallel end walls each with a centered, circular opening for moving the applicator over a glass tube or for moving a glass tube through, the waveguide emerging into the applicator tangent to the inside surface of the outer wall of the applicator.

21. The apparatus in claim 20, wherein the shortest distance between the outer wall of the applicator and circumference of the end wall opening is essentially the same as the short axis of the waveguide.

22. The apparatus in claim 21, further wherein the waveguide emerges into the applicator in a plane, which is tangent to the circumference of the two end wall openings.

23. The apparatus in claim 22, further comprising an oven capable of heating a glass tube to temperatures above about 1000° C. in which the apparatus and at least a portion of the waveguide are mounted.

24. The apparatus in claim 23, further comprising an oven capable of heating a glass tube to temperatures above about 1000° C. in which the apparatus and at least a portion of the waveguide are mounted.
